(19) United States
(12) Patent Application Publication
(10) Pub. No.: US 2009/0110877 A1
(43) Pub. Date: Apr. 30, 2009

(54) Method and substrate for making composite material parts by chemical vapour infiltration densification and resulting parts

(75) Inventors: Bruno Bernard, Pessac (FR); Stephane Goujard, Merignac (FR); Sebastien Bertrand, Moulis En Medoc (FR); Jacques Thebault, Bordeaux (FR)

Correspondence Address: WEINGARTEN, SCHURGIN, GAGNEBIN & LEBOVICI LLP, TEN POST OFFICE SQUARE, BOSTON, MA, 02109, US

(73) Assignee: SNECMA PROPULSION SOLIDE, Le Haillan Cedex (FR)

(21) Appl. No.: 11/921,342

(22) PCT Filed: Jun. 1, 2006
(86) PCT No.: PCT/FR2006/050499

§ 371 Date: Nov. 30, 2007

(30) Foreign Application Priority Data
Jun. 2, 2005 (FR) 05 05580

(51) Int. Cl. B32B 3/10; C23C 16/02; B05D 3/06; B05D 3/14

(52) U.S. Cl. 428/131; 427/248.1; 427/554; 427/532

(57) ABSTRACT

A composite material part is made by forming a fiber preform (20), forming holes (22) extending within the preform from at least one face thereof, and densifying the preform with a matrix formed at least in part by a chemical vapor infiltration (CVI) type process. The holes (22) are formed by removing material from the preform with fibers being ruptured, for example by machining using a jet of water under pressure, the arrangement of the fibers in the preform with the holes being substantially unchanged compared with the initial arrangement before the holes were formed. This enables the densification gradient to be greatly reduced, and it is possible in a single densification cycle to obtain a density that, in the prior art, required a plurality of cycles separated by intermediate scalping.

### BACKGROUND OF THE INVENTION

The present invention relates to making composite material parts by forming a fiber substrate and densifying the substrate with a matrix, itself formed by a chemical vapor infiltration (CVI) type method. A particular but non-exclusive field of application for the invention is making brake disks out of carbon/carbon (C/C) composite material, in particular for airplane brakes comprising a set of disks on a common axis alternating between stator disks and rotor disks. Nevertheless, the invention is applicable to making other parts out of C/C composite material or out of other composite material, in particular out of ceramic matrix composite (CMC) material.

Densifying porous substrates, such as fiber substrates or preforms, using CVI type methods, is well known.

In a conventional CVI process, the substrates for densification are placed in an oven. A reaction gas is admitted into the oven for the purpose of depositing the material constituting the matrix within the pores of the substrate by decomposing one or more ingredients of the gas, or by reaction between a plurality of ingredients, under determined temperature and pressure conditions.

A method is also known in which a substrate for densification is placed in a reactor in which it is heated in the presence of a precursor for the material that constitutes the matrix. The precursor is present in the liquid state in the reactor and the substrate is heated, e.g. by passing an electric current or by electromagnetic coupling with a coil, the substrate being made of electrically conductive fibers such as carbon fibers. Such a process is described in particular in U.S. Pat. Nos. 4,472,454, 5,397,595, or 5,389,152, and is sometimes referred to as densification by calefaction. Since the precursor is vaporized on coming into contact with the hot substrate, it is considered herein that that process is a densification process of the CVI type. In other words, the term “process of the CVI type”, or “process of the chemical vapor infiltration type”, is used in the present description and in the claims to cover both a conventional chemical vapor infiltration process and a densification process by calefaction.

A major difficulty with such CVI type processes is minimizing the densification gradient within substrates so as to obtain parts having properties that are as uniform as possible throughout their volume.

Matrix deposition tends to take place preferentially in the surface portions of the substrates, since they are the first to be encountered by the reaction gas. As a result, the gas that manages to diffuse to the core of a substrate is depleted, and the pores in the surface portions of the substrate are closed off early, thereby progressively reducing the ability of the gas to diffuse into the core. This leads to a densification gradient becoming established between the surface portions and the cores of substrates.

That is why, in particular when making parts that are thick, it is necessary in practice, once a certain degree of densification has been achieved, to interrupt the process and to remove the partially-densified substrates so as to machine their surfaces in an operation referred to as “scalping” that serves to re-open the surface pores. Densification can then be continued, with the reaction gas having easier access to diffuse into the cores of the substrates. By way of example, when making brake disks, it is general practice to perform at least two CVI densification cycles (cycles I1 and I2) with an intermediate scalping operation. In practice, a densification gradient is nevertheless observed in the parts that are finally obtained.

In order to avoid generating a densification gradient, and then possibly avoid scalping operations, it is indeed known to implement a CVI densification method that involves a temperature gradient, i.e. by heating the substrates in a non-uniform manner. Non-uniform heating by direct coupling between an induction coil and one or more annular substrates for densifying is described in documents U.S. Pat. 5,846,611 and EP 0 946 461. Matrix deposition in substrate zones that are less easily accessible to the gas is encouraged by raising these zones to a temperature that is higher than that of the other portions of the substrates. Nevertheless, that technique is limited to substrates of certain shapes and kinds and to certain arrangements of substrate loads in the oven.

U.S. Pat. No. 5,405,560 proposes encouraging access of the reaction gas to the interior of substrates constituted by annular fiber preforms for brake disks made of C/C composite material by providing passages in the form of holes that extend through the preforms, between their opposite faces. The holes are provided by inserting needles that push away the fibers in the preforms, without damaging them. During CVI densification, the holes provide the gas with shorter paths for reaching the central portions of the preforms. Tests carried out the Applicants have nevertheless shown that that technique presents limits in minimizing the densification gradient, as described below. Parallel document FR 2 616 779 does indeed mention the possibility of forming holes by means of a fluid under pressure that may partially destroy fibers, but it recommends avoiding damaging fibers.

Forming holes in brake disk blanks made of C/C composite material is also described in document FR 2 144 329. Nevertheless, that document relates to densifying brake disk fiber preforms by a liquid technique, i.e. by impregnating preforms with a carbon-precursor resin, which resin is cross-linked (hardened) and then carbonized or graphitized to form the carbon matrix. Holes are formed after the resin has hardened and before it is carbonized or graphitized, the holes serving to evacuate volatile species during carbonization or graphitization, and thus to avoid gas becoming trapped within the carbon matrix. That is a process that is completely different from CVI densification.

### OBJECT OF THE INVENTION

An object of the invention is to facilitate the diffusion of the reaction gas during a CVI type densification process, firstly in order to achieve practically uniform densification of fiber substrates in the fabrication of composite material parts, and secondly in order to reduce the number of densification cycles that are separated by intermediate scalping stages, or possibly even to achieve densification in a single cycle since it is no longer necessary to re-open the pores by an intermediate scalping stage.

This object is achieved by a method of making composite material parts comprising preparing a fiber substrate, forming holes extending in the substrate from at least one surface thereof, and densifying the substrate with a matrix formed at least in part by a chemical vapor infiltration type process, in which method the holes are formed in the substrate by removing fiber material therefrom with fibers being broken, the arrangement of the fibers in the preform provided with holes being substantially unchanged compared with their initial arrangement prior to the holes being formed.

As explained below, forming holes in the substrate by removing material, with fibers being broken, makes it possible, surprisingly, to obtain practically uniform densification of the substrate, whereas such a result is far from being obtained when the holes are formed by inserting needles that have a non-destructive effect on the fibers, as in the prior art. It is also possible to obtain in a single cycle a degree of densification that, in the prior art, required a plurality of cycles separated by intermediate scalping.

The holes may be formed by mechanical machining using a jet of water under high pressure.

In another implementation of the method, the holes may be formed by localized thermal action having a destructive effect on the material of the fibers, possibly in association with exposure to an oxidizing medium. This can apply in particular for carbon fibers. The localized thermal action may be produced by laser radiation.

In yet other implementations of the method, the holes may be formed by machining using a very high speed tool such as a drill bit, a driller, or a cutter, or by cutting out using a knife or a punch, or a die, or indeed by electro-erosion.

The holes may go through the substrate between two surfaces thereof, or they may be blind holes opening out into only one surface of the substrate.

Furthermore, the holes may be formed orthogonally relative to a surface of the substrate into which they open out, or they may extend in a direction that is not orthogonal.

With a substrate that forms an annular preform for a brake disk, the resulting holes may be holes that open out into at least one of the main faces of the preform perpendicularly to the axis of the preform, or holes that open out into the outer peripheral surface and possibly the inner peripheral surface thereof, the holes then being oriented in a direction that is radial or substantially radial, or the holes may be a combination of both types of hole.

The mean diameter of the holes is selected to avoid them becoming closed off by deposition of the matrix material before the end of the CVI densification process. A mean diameter lying in the range about 0.05 millimeters (mm) to 2 mm may be selected, for example. The holes are of small diameter and after densification they have no functional role during subsequent use, for example they do not provide any cooling function for a brake disk.

The density of the holes is selected to be sufficient to provide the reaction gas with a short path to all portions of the substrate that it is desired to densify in practically uniform manner. By way of example, it is possible to select a density lying in the range about 0.06 holes per square centimeter (holes/cm²) to 4 holes/cm², with this density being measured in terms of number of holes per unit area in a midplane or on a mid-surface of the substrate. In other words, the distance or pitch between the axes of adjacent holes preferably lies in the range about 0.5 centimeters (cm) to 4 cm.

The density of holes in the fiber substrate may be constant so as to provide a short path for the reaction gas in the same manner to all portions of the substrate for densifying. In a variant, hole density may vary, in which case it is possible to select the density to be greater in those portions of the substrate where, in the absence of holes, the path for the gas is longer and the amount of matrix material delivered to the core of the substrate is smaller, and to select a density that is smaller or even zero in those portions of the substrate where, even in the absence of holes, the amount of matrix material delivered is high enough. Thus, for substrates in the form of annular preforms for brake disks, in particular for airplane brake disks, with holes opening out into at least one of the main faces of the substrate, the density of the holes may vary and may decrease between a central portion of the substrate corresponding to a rubbing track of the disk, and portions of the substrate that are adjacent to its outer and inner circumferential surfaces. It is possible to form holes in the central portion only of the substrate that corresponds to the rubbing track of the brake disk that is to be made.

The invention also provides a fiber substrate for making a composite material part, the substrate having holes that extend into the substrate from at least one surface thereof, in which substrate the density per unit volume of fibers in the vicinity of the walls of the holes in the substrate is not significantly greater than the density per unit volume of the fibers in other portions of the substrate.

According to a feature of the substrate, the holes are defined by limit zones where fibers have been eliminated or ruptured.

The invention also provides a composite material part comprising fiber reinforcement densified by a matrix obtained at least in part by a chemical vapor infiltration type process and presenting holes that extend into the part from at least one surface thereof, in which part, the fiber reinforcement is made from a substrate as defined above, or a part in which the density per unit volume of reinforcing fibers in the vicinity of the walls of the holes is not significantly greater than the density per unit volume of fibers in other portions of the part.

### BRIEF DESCRIPTION OF THE DRAWINGS

The invention can be better understood on reading the following description given by way of non-limiting indication and made with reference to the accompanying drawings, in which:

FIG. 1 shows the successive steps in making a composite material part in an implementation of a method in accordance with the invention;

FIG. 2 is a diagrammatic perspective view of an annular fiber preform for a brake disk in which holes are formed;

FIG. 3 is a fragmentary section view on a larger scale on plane III of FIG. 2;

FIGS. 4 to 6 are section views showing variant forms of holes that open out to at least one of the main faces of an annular fiber preform for a brake disk;

FIGS. 7 to 10 show variant arrangements of holes at the surface of a fiber substrate;

FIGS. 11 and 12 are views showing variant forms of holes opening out at least in the outer peripheral face of an annular preform for a brake disk;

FIG. 13 is a diagram showing a brake disk obtained after densification, CVI, and final machining, using a preform of the kind shown in FIG. 2;

FIG. 14 is a plan view of a fiber preform for a rotor disk of an airplane brake in which holes have been formed at varying densities;

FIG. 15 is a highly diagrammatic view showing annular fiber preforms for brake disks loaded at a stack in a CVI densification oven; and

FIG. 16 is a graph plotting curves that show how the density of a disk obtained after densifying the FIG. 14 preform varies between the inner and outer circumferences, and by way of comparison the density varies in a disk after densifying a similar preform, but in which holes have not been formed.

### DETAILED DESCRIPTION OF EMBODIMENTS OF THE INVENTION

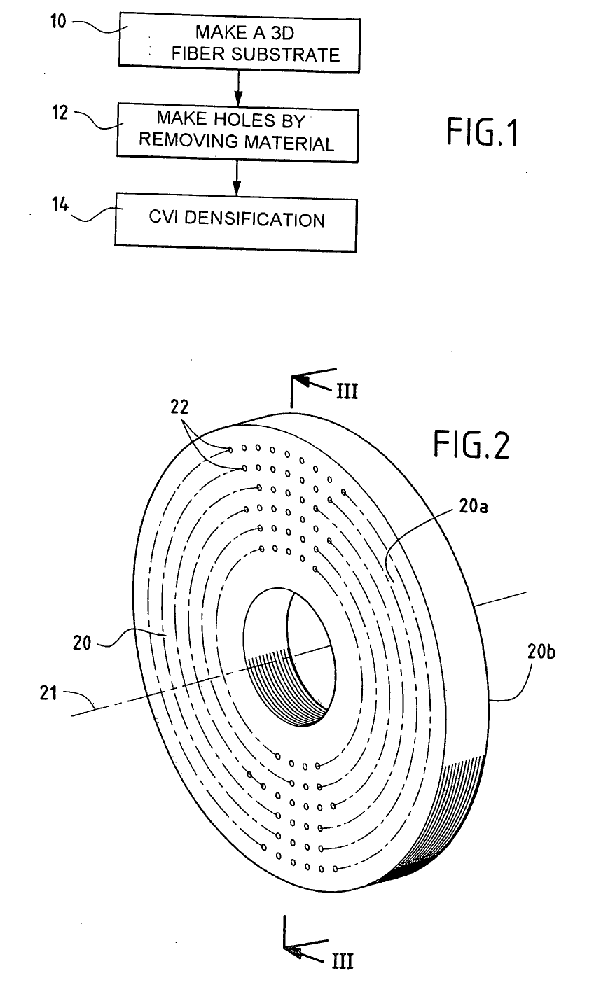

A first step 10 of the method shown in FIG. 1 consists in making a three-dimensional (3D) fiber substrate or fiber preform having a shape close to the shape of a composite material part that is to be obtained. The techniques for making such fiber preforms are well known.

It is possible to start from one-dimensional (1D) fiber elements, such as yarns or tows that are wound on a former or a mandrel or that are used to form a 3D substrate directly by three-dimensional weaving, knitting, or braiding.

It is also possible to start from two-dimensional (2D) fiber textures such as woven fabrics, knits, flat braids, thin felts, unidirectional (UD) webs made up of mutually parallel yarns or tows, or indeed multidirectional (nD) webs made up of UD webs superposed in different directions and bonded together, e.g. by light needling or by stitching. Plies made up of such 2D textures are superposed by being wound on a former or a mandrel or by being draped on a former or a support, and they are bonded together, e.g. by needling, by stitching, or by implanting yarns through the plies, in order to obtain a 3D substrate.

A 3D substrate can also be obtained in the form of a thick felt made by needling randomly oriented discontinuous fibers.

A 3D substrate as obtained in this way can be used directly as a fiber preform for a part that is to be obtained. It is also possible to form a desired fiber preform by cutting out from a 3D substrate in order to obtain the desired shape.

The fibers constituting the preform are selected as a function of the application of the composite material part that is to be obtained. With thermostructural composite materials, i.e. materials having good mechanical properties and the ability to conserve them at high temperatures, the fibers of the fiber reinforcement of the material are typically made of carbon or of ceramic. The preform can be made from such fibers, or from fibers that are precursors for carbon or for ceramic and that can be better suited to withstanding the various textile operations used for making 3D fiber substrates. Under such circumstances, after the substrate or the preform has been made, the precursor is transformed into carbon or ceramic, usually by heat treatment.

A second step 12 of the method consists in forming holes in the preform so as to improve access of a reaction gas to the core of the preform during subsequent CVI type densification. When the preform is made of fibers of material obtained by transforming a precursor material, the holes may be formed in the preform after the precursor has been transformed or before said transformation. If they are made beforehand, account should be taken of any shrinkage that might occur during the transformation of the precursor so as to ensure that holes are obtained of desired size.

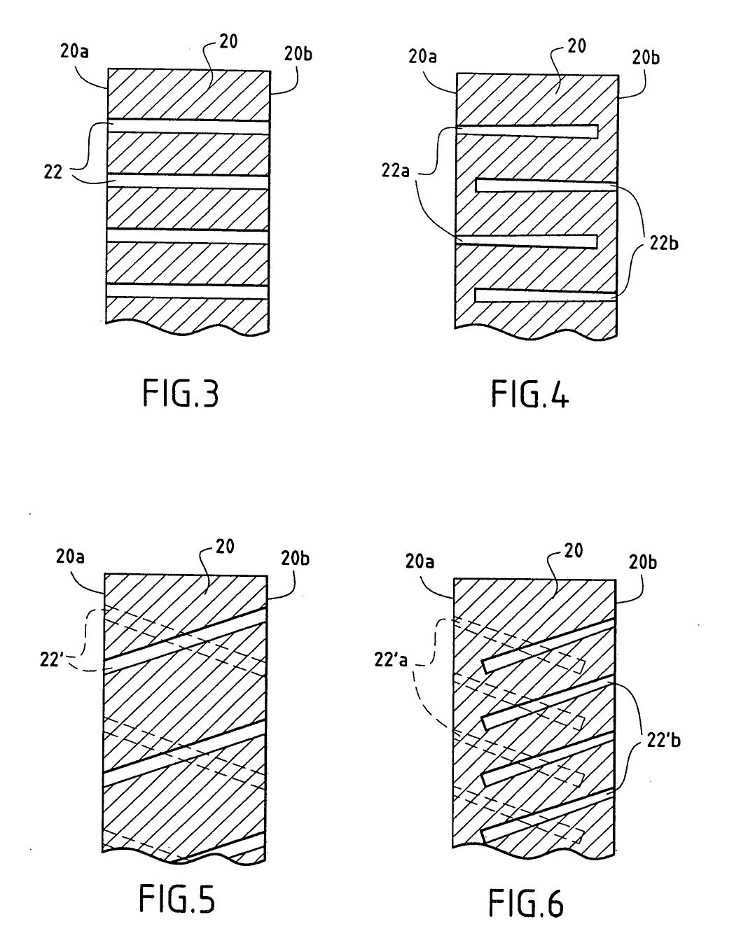

FIGS. 2 and 3 show an annular fiber preform 20 made of carbon fibers for fabricating a brake disk out of carbon/carbon (C/C) material. Such a preform can be obtained by being cut out from a 3D fiber substrate in the form of a plate, e.g. made by superposing and needling plies of cloth or unidirectional or multidirectional webs of preoxidized polyacrylonitrile (PAN), a precursor for carbon. The preform can also be obtained by superposing and needling annular plies cut out from unidirectional or multidirectional cloths or webs of preoxidized PAN fibers. After the annular preform has been made out of preoxidized PAN fibers, the preoxidized PAN is transformed into carbon by heat treatment. Reference can be made for example to U.S. Pat. Nos. 4,790,052 and 5,792,15.

Holes 22 are formed in the preform 20 parallel to its axis 21 and extend through its entire thickness between the opposite main faces 20a and 20b into which they open out, which faces are perpendicular to the axis 21.

In a variant, as shown in FIG. 4, blind holes 22a, 22b are formed in the preform, the holes 22a opening out solely into the face 20a, while the holes 22b open out solely into the face 20b. It should be observed that the holes 22a, 22b extend over a very large fraction of the thickness of the preform.

In another variant, the holes may be formed on the bias, i.e. their axes may form a non-zero angle relative to the normal to the faces 20a, 20b or to the axis of the preform 20, and this can apply to through holes 22′ (FIG. 5) or to blind holes 22′a, 22′b (FIG. 6).

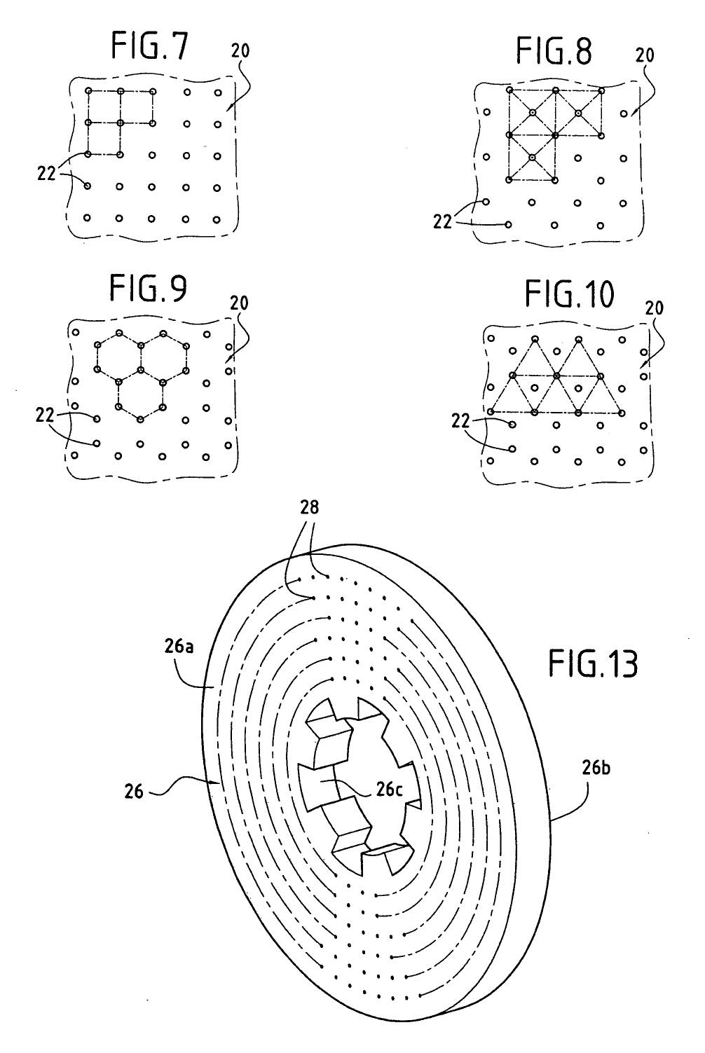

In FIG. 2, the holes 22 are disposed at regular intervals along concentric circles. They could be disposed along a spiral line. In addition, regardless of whether the fiber preforms 20 are annular or of some other shape, the holes 22 could be disposed in other patterns, e.g. at the vertices of quadrangles (FIG. 7), at the vertices and at the centers of quadrangles (FIG. 8), at the vertices of hexagons (FIG. 9), or at the vertices of equilateral triangles (FIG. 10). For a given density of holes, the equilateral triangle disposition is the most favorable for minimizing the path length followed by a gas in order to reach all points within the preform from the holes.

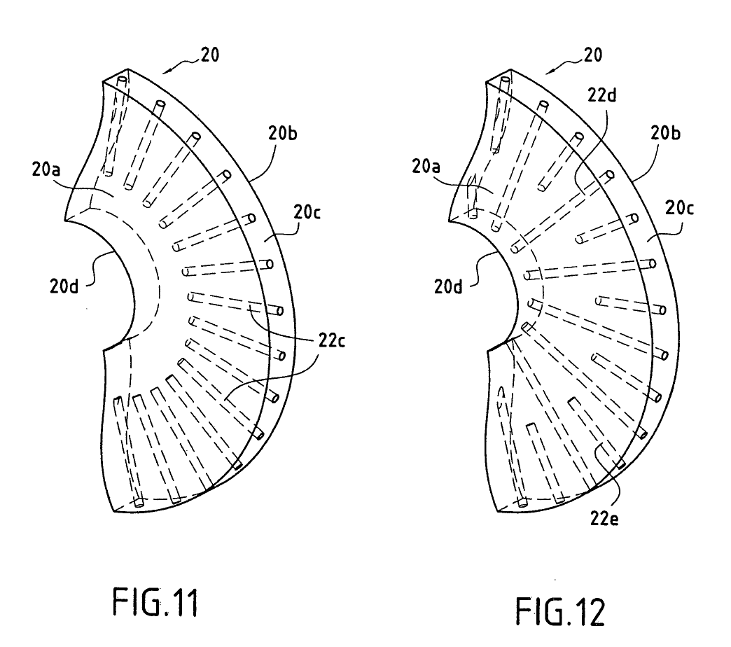

FIGS. 11 and 12 show another embodiment in which holes are formed that open out not into one and/or the other of the main faces 20a, 20b of the preform 20, but into the outer circumferential peripheral surface 20c, and optionally into the inner circumferential peripheral surface 20d, with the holes extending radially or substantially radially.

In FIG. 11, holes 22c are formed in the middle portion of the disk. The holes open out into the outer surface 20c and extend radially over a major fraction of the distance between the surface 20c and the inner circumferential surface 20d, but without opening out therein.

In FIG. 12, holes 22d, 22e are formed in the middle portion of the disk, the holes 22d being through holes extending radially between the surface 20c and the surface 20d, while the holes 22e are non-through holes that open out solely into the surface 220c and that extend over a fraction, about half, of the distance between the surfaces 20c, 20d.

The holes 22e alternate with the holes 22d and seek to minimize the non-uniformity of hole density between the surfaces 20c and 20d. For the same reason, intermediate holes of limited depth could also be provided in the example of FIG. 11.

Although FIGS. 11 and 12 show holes occupying a single row in the middle portion of the disk, it would naturally also be possible, depending on the thickness of the disk, to provide a plurality of rows of holes.

According to a characteristic of the method in accordance with the invention, the holes are formed in the preform by removing material.

For this purpose, it is possible it is possible to use a technique of drilling by means of a jet of water under pressure that can be used to form through holes or blind holes. The water used may optionally be charged with solid particles. Drilling may be performed using one or more water jet pulses, or continuously. When the diameter of the holes is large relative to the diameter of the jet, a hole can be drilled by cutting out, i.e. by cutting around the circumference each of the holes to be made. Depending on the drilling technique used, the holes may be slightly frustoconical in shape, as shown in FIGS. 4 and 6. The diameter of the holes then increases going away from the face where water jet machining is performed, because the water jet becomes dispersed, or mainly because water charged with solid machining debris is more abrasive. With through holes, about 50% of the holes are machined from one of the faces and the other holes from the other face so as to ensure that the density of voids created by the holes is substantially uniform throughout the thickness of the preform. For the same purpose, in FIG. 4, about the same number of holes are formed from each of the faces of the preform.

Another possible technique for forming holes that is appropriate when the fiber material can be eliminated by heat is to produce a localized thermal action, in particular by laser radiation. In particular with carbon fibers, such thermal action in an oxidizing medium, e.g. in air, enables the material of the fibers to be eliminated by being oxidized. Various types of laser source can be used, for example of the carbon dioxide type or of the yttrium aluminum garnet (YAG) type. The use of laser radiation enables hole depth to be controlled when making non-through holes, it enables holes to be made by being cut out, and it makes it easy to control the orientation of the holes.

Other techniques can also be used to form the holes by removing material. Recourse can be made to techniques of machining by means of a tool driven at high speed, such as a drill bit, a driller, or a cutter, to cutting by means of a knife, a punch, or a die, or to electro-erosion. Such machining techniques are well known.

Forming holes by removing material by implementing the above-mentioned techniques has a destructive effect on the fibers of the preform but does not change the arrangement of the fibers in the vicinity of the walls of the holes compared with their initial arrangement prior to the holes being formed. Thus, the material initially situated in the locations of the holes is advantageously completely removed or eliminated, so that the resulting holes are defined by limit zones of fiber elimination or rupture, and the density of the fibers in the preform per unit volume in the vicinity of the walls of the holes is not increased, unlike what would happen if the holes were to be formed by inserting needles to push back the fibers into the zones constituting the walls of the holes.

During the subsequent process of CVI type densification, access for the reaction gas to the material of the fiber preform is no more restricted when going through the walls of the holes than when going through the outside surfaces of the preform, unlike what would apply if the fibers had been pushed back into the hole wall zones during hole formation, since that would lead to a local increase in the density per unit volume of the fibers at the surfaces of the holes and to premature closing off of the walls of the holes during densification. Such premature closing off of the walls of the holes, which would deprive them of their effectiveness, is thus avoided during the course of the densification process.

In the preform, and also in the composite material part obtained after densification by the CVI type process, the density of fibers per unit volume in the vicinity of the walls of the holes is not significantly greater than the density per unit volume of the fibers in other portions of the preform or the part. Thus, non-uniformity is avoided in the properties of the composite material.

The mean diameter of the holes is selected to be sufficiently large to avoid them becoming closed off before the end of the CVI type densification process since that would prevent them from performing their function, while nevertheless remaining limited so as to avoid affecting the behavior of the composite material parts obtained after densification, with this applying particularly since above a certain value for hole diameter, access for the gas is not really improved, even at the end of the CVI type process.

This mean diameter can thus vary as a function of the thickness of the matrix to be deposited on the fibers, of the dimensions of the parts to be made, and of the utilization of the parts.

In general, in particular for airplane brake disk preforms, the mean diameter of the holes may be selected to have a value lying in the range about 0.05 mm to 2 mm.

The density of the holes is selected to be sufficient, in association with the diameter, to provide a short path to be followed by the reaction gas to reach any portion of the preform during CVI type densification, while nevertheless remaining limited so as to avoid affecting the behavior of the composite material part obtained after densification. This density may be adapted to the dimensions of the parts to be made and to its utilization.

In general, and in particular for airplane brake disks preforms, the density of the holes can be selected to be equal to a value lying in the range about 0.06 holes/cm² to 4 holes/cm². In FIGS. 2 to 6, this density is measured in a midplane of the preform so as to cover embodiments in which blind holes are formed. It can also be measured on one of the faces when the holes are through holes as in FIGS. 3 and 5. In FIGS. 11 and 12, the density is not constant, and account may then be taken of a mean density.

In other words, it is preferable for the distance or pitch between the axes of adjacent holes to be selected to have a value that lies in the range 0.5 cm to 4 cm. In the embodiments of FIGS. 11 and 12, that is a mean pitch.

In a given preform, the holes may be of the same diameter or of different diameters.

Similarly, hole density without a given preform may be constant or it may vary.

After the holes have been formed, the preform is densified by a CVI type process (step 14). Processes for CVI type densification with carbon or ceramic matrices are well known. A precursor is used that is adapted to the nature of the matrix material that is to be deposited.

Depending on circumstances, and in particular as a function of the thickness of the preform that is to be densified and the density that is to be achieved, it may optionally be desirable to scalp at least the exposed faces of the preform. If such scalping is performed, step 14 comprises a first densification cycle I1 followed by machining the surface of the preform, and then by a second densification cycle I2.

FIG. 13 shows a brake disk 26 as obtained after CVI type densification of a preform of the kind shown in FIG. 2 and after it has been machined to its final dimensions, with notches 26c and tenons 26d being formed so as to enable the disk to be secured mechanically. In this example, the disk is a stator disk for an airplane brake having two opposite friction faces 26a and 26b. It should be observed that holes 28 corresponding to the holes formed in the preform are visible. Nevertheless, because of their small diameter, these holes do not perform any functional role, such as a cooling function, while the brake disk is subsequently in use.

In the example shown in FIGS. 2 and 7, holes are formed throughout the volume. In a variant, hole formation could be restricted to certain zones of the preform or there could be a greater density of holes in certain zones, for example with a brake disk, the zones corresponding to the friction faces, and possibly the zones corresponding to the tenons providing mechanical connection with the disk.

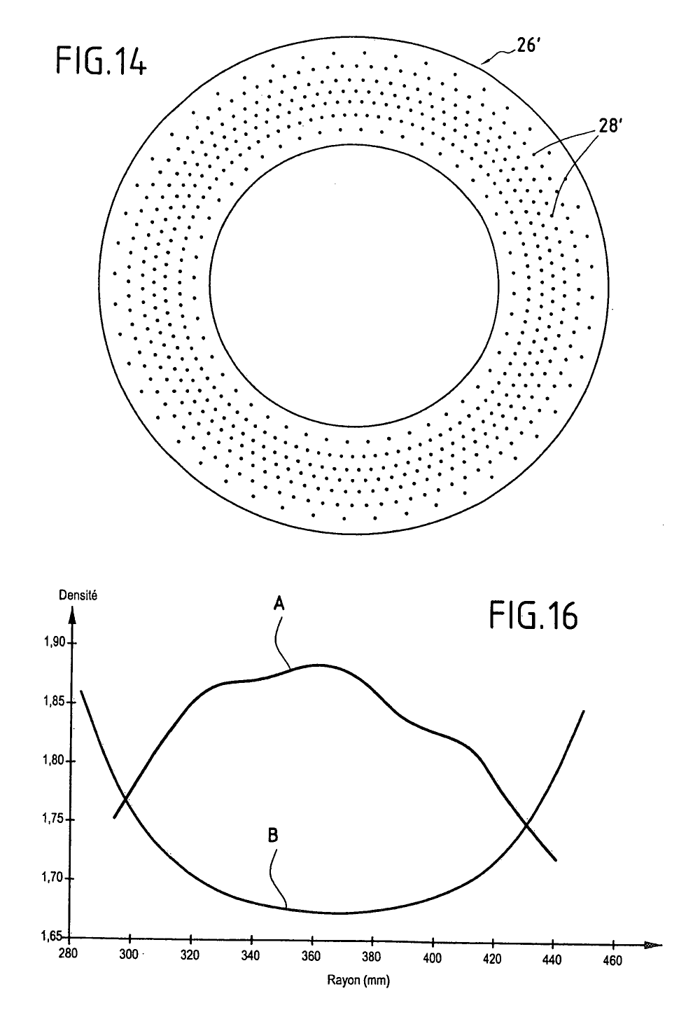

Thus, FIG. 14 is a diagram of an airplane brake disk 26′ before final machining, as obtained after densifying an annular preform in which holes have been formed at varying density, the holes being through holes parallel to the axis of the disk and opening out into the main faces of the preform. As shown by the disposition of the holes 28′ that remain after densification, the density of the holes formed in the preform is at a maximum in the vicinity of the rubbing track of the disk, in the central portion thereof, with said density decreasing between said central portion and in the portions adjacent to the inner and outer circumferential surfaces of the disk. This favors uniform densification in the portion of the disk that is used during braking. In some circumstances, it is possible to envisage forming holes that seek to encourage densification also in other portions of the densification, i.e. portions other than those corresponding to the rubbing track of the disk, e.g. in portions of the preform that correspond to portions in relief or tenons that are formed at the inner or outer circumference to provide a mechanical connection between the disk and a stationary or rotary member.

Although the above description relates to annular fiber preforms for brake disks, it is clear that the invention is applicable to all types of preform for use in making composite material parts, and in particular thick parts for which the problem of uniform densification arises.

In addition, the invention is applicable independently of the nature of the fibers of the preforms and of the matrix that is deposited in order to densify them by a CVI type process.

It should also be observed that the operation of densifying the perforated fiber preform of the invention can include a first stage of partial densification using a liquid technique prior to a second stage of densification of the CVI type. Densification by a liquid technique, as is well known, consists in performing at least one cycle of impregnating the preform with a liquid composition containing a liquid precursor for the matrix material. The precursor is typically a resin, e.g. an organic resin that is a precursor for carbon. After drying, to eliminate any solvent, and after the resin has been polymerized, heat treatment is performed to transform the precursor.

### EXAMPLE 1

Annular fiber preforms made of carbon fibers for airplane brake disks of C/C composite material were made as follows.

Multidirectional webs were obtained by superposing three unidirectional webs of preoxidized PAN fibers, extending at angles of +60° relative to one another and bonded together by needling. The multidirectional webs were superposed and needled together progressively as they were being superposed so as to obtain a needled plate from which annular preforms of preoxidized PAN were cut out.

The preoxidized PAN preforms were subjected to heat treatment about 1600° C. to transform the PAN into carbon. This produced carbon fiber annular preforms with inner and outer diameters of 26 cm and 48 cm, a thickness of 3.5 cm, and with a fiber volume percentage of about 23%, the fiber volume percentage being the percentage of the apparent volume of the preform that is occupied by the fibers.

Some of the preforms were pierced with through holes parallel to the axis, formed by jets of water under pressure, at a substantially constant density of about 1 hole/cm². Preforms were thus obtained with holes having respective diameters of about 0.2 mm for preforms Al, A2, of about 0.5 mm for preforms B1, B2, and of about 1 mm for preforms C1, C2.

By way of comparison, holes were made in another preform D by inserting needles of diameter equal to 2 mm, at a density of about 1 hole/cm², the needles subsequently being withdrawn for CVI densification.

A load of preforms was prepared in the form of an annular stack made up essentially of non-pierced preforms E, with preforms A1, A2, B1, B2, C1, and C2 being inserted in the stack between pairs of non-pierced preforms E1 and E2.

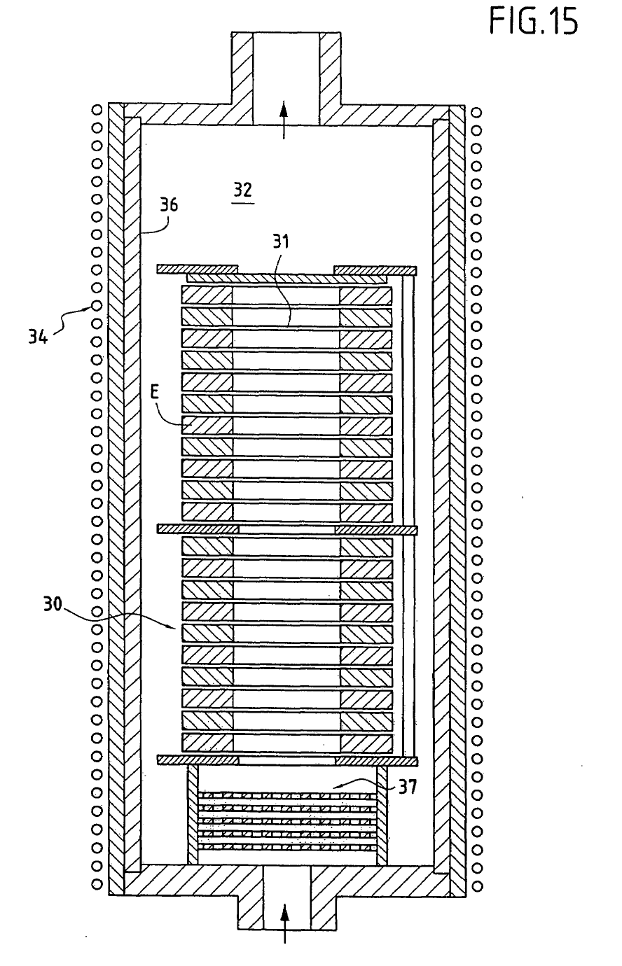

FIG. 15 shows such a load in the form of a stack 30 inserted into the reaction chamber 32 of a CVI densification oven for performing CVI densification of the “directed flow” type as described in U.S. Pat. No. 5,904,957. Briefly, the oven is heated by inductive coupling between a coil 34 and a graphite susceptor 36 defining the reaction chamber, with insulation being interposed between the coil and the susceptor. A reaction gas is admitted through the bottom of the susceptor 36, passes through a preheating zone 37, and is directed into the inside volume 31 of the stack that is closed at its top end. The gas flows through the inside volume of the chamber 32 outside the stack 30, passing through gaps provided by means of spacers (not shown) between the preforms, and diffusing through the gaps. The effluent gas is extracted through the cover of the susceptor by suction by means of a pump unit that establishes the desired pressure level within the chamber.

CVI densification of substrates with a pyrolytic carbon matrix was performed using a reaction gas based on natural gas, at a pressure of about 5 kilopascals (kPa) and at a temperature of about 1000° C.

Densification was performed in two cycles I1, I2 separated by a scalping operation for which the load was removed from the oven. The cycle I1 was performed under predetermined conditions enabling the relative density of the preforms E to be raised to a value of about 1.6. After scalping by machining the main faces of the partially-densified preforms in order to bring them to a thickness close to that of the disks to be made, the cycle I2 was performed under predetermined conditions for bringing relative density up to about 1.8. For the cycle I2, the oven was loaded by placing the partially-densified preforms E1, A1, A2, B1, B2, C1, C2, and E2 in that order back into the oven.

The same procedure was used for densifying a stack load made up of E type substrates in two cycles I1 and I2, with the exception of a substrate D which was inserted in the stack adjacent to a substrate E3.

Table I below gives the density values measured for the disks A1, A2, B1, B2, C1, C2, E1, and E2 after the cycles I1 and I2, and for the disks E3 and D after cycle I2. It can be seen that the final densities obtained for the disks A1, A2, B1, B2, C1, and C2 were significantly greater than those for the disks D, E1, and E2, and that the density of the disks D is far from being increased to the same extent at the end of cycle I2 compared with the density of the disk E3.

TABLE I

| Starting | | Density at the | Density at the |
|---|---|---|---|
| preform | Holes | end of cycle I1 | end of cycle I2 |
| E1 | None | 1.58 | 1.81 |
| A1 | Ø 0.2 mm | 1.59 | 1.88 |
| A2 | Ø 0.2 mm | 1.56 | 1.88 |
| B1 | Ø 0.5 mm | 1.56 | 1.89 |
| B2 | Ø 0.5 mm | 1.57 | 1.89 |
| C1 | Ø 0.1 mm | 1.57 | 1.89 |
| C2 | Ø 1 mm | 1.59 | 1.89 |
| E2 | None | 1.61 | 1.80 |
| E3 | None | | 1.79 |
| D | Insert Ø | | 1.81 |
| | 2 mm needles | | |

In order to verify whether or not that there was a densification gradient, blocks of substantially rectangular shape were cut out from disks A1, E1, D, and E2 as obtained after cycle I2, along radii of those disks. For each block, density was measured at various zones Z1 to Z5 between the inner diameter and the outer diameter in the vicinity of one face, in the vicinity of the other face, and in the radially middle portion.

Table II below gives the density values measured. It can be seen that that a remarkable result was obtained with the disk A1 made in accordance with the invention since its density is practically uniform (variation by less than 1.7%).

With the disks E1 and E3 obtained from a preform without holes, considerable variation in density was observed, revealing the existence of a fairly steep densification gradient in spite of the intermediate scalping operation (variations of 8.1% to 7.7%, respectively).

A variation in density of 6% was measured for the disk D, which variation is less than that observed with disks E1 and E3, but nevertheless still very substantial.

TABLE II

| | | | Density at the end of cycle I2 | | | | |
|---|---|---|---|---|---|---|---|
| Starting | | | | | | | Z5 |
| preform | | Holes | Z1 | Z2 | Z3 | Z4 | (outer radius) |
| A1 | face | Ø 0.2 mm | 1.86 | 1.87 | 1.88 | 1.87 | 1.87 |
| | center | | 1.86 | 1.86 | 1.86 | 1.85 | 1.85 |
| | face | | 1.87 | 1.87 | 1.87 | 1.86 | 1.86 |
| E1 | face | None | 1.83 | 1.77 | 1.78 | 1.79 | 1.84 |
| | center | | 1.80 | 1.69 | 1.70 | 1.69 | 1.78 |
| | face | | 1.81 | 1.76 | 1.76 | 1.78 | 1.82 |
| D | face | Insert | 1.82 | 1.79 | 1.77 | 1.79 | 1.80 |
| | center | Ø 2 mm | 1.77 | 1.72 | 1.71 | 1.72 | 1.79 |
| | face | needles | 1.79 | 1.77 | 1.76 | 1.78 | 1.79 |
| E3 | face | None | 1.80 | 1.78 | 1.75 | 1.77 | 1.81 |
| | center | | 1.75 | 1.70 | 1.67 | 1.71 | 1.78 |
| | face | | 1.75 | 1.73 | 1.74 | 1.76 | 1.81 |

Thus, the method of the invention is remarkable in that it enables the degree of densification to be increased (and thus for given target density, it enables densification time to be shortened), while practically eliminating the densification gradient, results that the prior art method (forming holes by inserting needles) does not obtain.

### EXAMPLE 2

The procedure was substantially the same as in Example 1, but without intermediate scalping, preparing a load in the form of a stack of annular carbon fiber preforms for stator disks and rotor disks with different preform thicknesses lying in the range 24 mm to 36 mm, and with preforms that have been performed by a jet of water under pressure (0.5 mm diameter holes at a substantially constant density of 1 hole/cm²), and with preforms that were not perforated.

A CVI densification cycle was performed to provide a pyrolytic carbon matrix, and it was interrupted at three-quarters of its total duration in order to measure the relative density of the partially-densified preforms. Table III below gives the intermediate and final mean relative density values as measured after three-quarters of the duration of the cycle and at the end of the cycle.

TABLE III

| | Type of | Thickness | Intermediate | Final |
|---|---|---|---|---|
| Preform | disk | (mm) | density | density |
| Non-perforated | Stator | 24 | 1.65 | 1.74 |
| | | 30 | 1.65 | 1.72 |
| | | 36 | 1.68 | 1.70 |
| | Rotor | 28.5 | 1.71 | 1.75 |
| | | 33 | 1.71 | 1.77 |
| With | Stator | 24 | 1.66 | 1.79 |
| holes | | 30 | 1.69 | 1.80 |
| | | 36 | 1.73 | 1.82 |
| | Rotor | 28.5 | 1.75 | 1.83 |
| | | 33 | 1.74 | 1.83 |

The desired target density (1.78) was not reached at the intermediate stage, but a greater density was observed in preforms provided with holes. At the end of the cycle, the target was achieved for all of the preforms having holes (bold values) and was not achieved for any of the non-perforated preforms.

This example shows that C/C composite material brake disks having the required density can be obtained in a single cycle, without intermediate scalping, by forming holes in the preform in accordance with the invention.

### EXAMPLE 3

The procedure was substantially the same as in Example 1, but without intermediate scalping (a single densification cycle of duration practically identical to that of the cycle in Example 2), by forming a load as a stack of annular carbon fiber preforms for brake disks, comprising non-perforated preforms and preforms perforated with different densities of holes. The holes were through holes parallel to the axis and with a diameter of 0.5 mm, and they were formed by a water jet under pressure using a square array pattern as shown in FIG. 7.

The cycle was interrupted at the end of two-thirds of its total duration in order to measure the mean intermediate density then reached. Table IV below gives the intermediate and end-of-cycle measured mean relative density values for preforms presenting differing densities of holes. The rate of density increase between the intermediate pause and the end of the cycle is also given (in density points per hour), showing deposition rate over the final hours.

TABLE IV

| | | End-of- | Rate of density |
|---|---|---|---|
| | Intermediate | cycle | increase |
| Holes | density | density | (density point/h) |
| None | 1.661 | 1.772 | 6.27 × 10⁻⁴ |
| 2 cm × 2 cm | 1.650 | 1.793 | 8.08 × 10⁻⁴ |
| array | | | |
| 1.5 cm × 1.5 cm | 1.661 | 1.817 | 8.81 × 10⁻⁴ |
| array | | | |
| 1 cm × 1 cm | 1.690 | 1.852 | 9.15 × 10⁻⁴ |
| array | | | |

It can be seen that increasing the density of the holes leads to deposition taking place at a higher rate in the final portion of the densification cycle.

### EXAMPLE 4

The procedure was substantially as in Example 1, but without intermediate scalping, forming a load as a stack of annular carbon fiber preforms for brake disks, comprising non-perforated preforms and a preform perforated with holes in the disposition shown in FIG. 14. The perforated preform was a rotor disk preform having outer and inner diameters of 46.8 cm and 26.7 cm respectively, a thickness of 3.5 cm, and 576 through holes with a diameter of 0.5 mm. The holes were formed using a water jet under pressure parallel to the axis of the preform.

Curve A in FIG. 16 shows how measured density varied as a function of disk radius at the end of a densification cycle of standard duration, of the same order of magnitude as in Examples 2 and 3. By way of comparison, curve B shows the density variation as measured on a disk obtained from a preform having the same dimensions but no perforations.

It can be seen that the greater density of holes in the central portion of the preform enables a greater density of disk material to be obtained in this portion, whereas the disk obtained from a non-perforated preform presents a strong density gradient with a minimum value in the central portion of the preform.

1. A method of making composite material parts comprising preparing a fiber substrate, forming holes extending in the substrate from at least one surface thereof, and densifying the substrate with a matrix formed at least in part by a chemical vapor infiltration type process,
in which method the holes are formed in the substrate by removing fiber material therefrom with fibers being broken, the arrangement of the fibers in the preform provided with holes being substantially unchanged compared with their initial arrangement prior to the holes being formed.

2. A method according to claim 1, in which the holes are formed by machining with a jet of water under pressure.

3. A method according to claim 1, in which the holes are formed by localized thermal action on the fiber material of the preform.

4. A method according to claim 3, in which the holes are formed under the effect of laser radiation.

5. A method according to claim 3, in which the holes are formed by eliminating fiber material by oxidation.

6. A method according to claim 1, in which the holes are formed by machining using a high speed tool.

7. A method according to claim 1, in which the holes are formed by cutting out.

8. A method according to claim 1, in which the holes are formed by electro-erosion.

9. A method according to claim 1, in which the substrate is an annular preform and the holes are formed to open out into at least one of the main faces of the preform.

10. A method according to claim 1, in which the substrate is an annular preform and holes are formed that open out into at least the outer peripheral surface of the preform.

11. A method according to claim 1, in which the holes are of a mean diameter lying in the range 0.05 mm to 2 mm.

12. A method according to claim 1, in which the density of the holes in the substrate lies in the range 0.06 holes/cm2 to 4 holes/cm2.

13. A method according to claim 1, in which the density of the holes in the substrate varies.

14. A method according to claim 13, in which the substrate forms an annular preform for a brake disk and holes are formed that open out into at least one of the main faces of the preform, the density of the holes varying and decreasing between a central portion of the substrate corresponding to a friction track of the disk and portions of the substrate that are adjacent to the inner and outer circumferential surfaces thereof.

15. A method according to claim 1, in which the distance between the axes of adjacent holes lies in the range 0.5 cm to 4 cm.

16. A fiber substrate for making a composite material part, the substrate including holes that extend within the substrate from at least one surface thereof,
in which substrate the density per unit volume of fibers in the vicinity of the walls of the holes in the substrate is not significantly greater than the density per unit volume of the fibers in other portions of the substrate.

17. A substrate according to claim 16, in which the holes are defined by limit zones of fiber elimination or rupture.

18. A substrate according to claim 16, in which the holes have a mean diameter lying in the range 0.05 mm to 2 mm.

19. A substrate according to claim 16, in which the density of holes in the substrate lies in the range 0.06 holes/cm2 to 4 holes/cm2.

20. A substrate according to claim 16, in which the density of holes in the substrate varies.

21. A substrate according to claim 20, forming an annular preform for a brake disk, in which the holes open out into at least one of the main faces of the substrate.

22. A substrate according to claim 21, in which the density of holes varies, decreasing between a central portion of the substrate corresponding to a friction track of the disk, and portions of the substrate adjacent to the inner and outer circumferential surfaces thereof.

23. A substrate according to claim 16, forming an annular preform, in which holes open out at least into the outer peripheral surface of the substrate.

24. A composite material part comprising fiber reinforcement densified by a matrix obtained at least in part by a chemical vapor infiltration type process and presenting holes (28) extending within the part from at least one surface thereof, the fiber reinforcement being formed by a substrate according to claim 16.

25. A composite material part comprising fiber reinforcement densified by a matrix obtained at least in part by a chemical vapor infiltration type process and presenting holes extending within the part from at least one surface thereof,
in which part the density per unit volume of reinforcing fibers in the vicinity of the walls of the holes is not significantly greater than the density per unit volume of the fibers in other portions of the part.

26. A method according to claim 4, in which the holes are formed by eliminating fiber material by oxidation.

27. A composite material part comprising fiber reinforcement densified by a matrix obtained at least in part by a chemical vapor infiltration type process and presenting holes extending within the part from at least one surface thereof, the fiber reinforcement being formed by a substrate in which the holes are defined by one or more of: limit zones of fiber elimination or rupture a mean diameter lying in the range 0.05 mm to 2 mm; a density of holes in the substrate lying in the range 0.06 holes/cm2 to 4 holes/cm2; the density of holes in the substrate varying; opening out into at least one of the main faces of the substrate; the density of holes varying, decreasing between a central portion of the substrate corresponding to a friction track of the disk, and portions of the substrate adjacent to the inner and outer circumferential surfaces thereof.
